(19) United States
(12) Patent Application Publication
(10) Pub. No.: US 2016/0048152 A1
(43) Pub. Date: Feb. 18, 2016

(54) CURRENT MIRROR WITH DEPLETION MODE MOS AND EMBEDDED NOISE FILTER

(71) Applicant: Texas Instruments Incorporated, Dallas, TX (US)

(72) Inventors: Bhavesh G. Bhakta, Richardson, TX (US); Mustafa U. Erdogan, Allen, TX (US)

(21) Appl. No.: 14/827,080

(22) Filed: Aug. 14, 2015

Related U.S. Application Data
(60) Provisional application No. 62/037,428, filed on Aug. 14, 2014.

(51) Int. Cl. G05F 3/16; H03B 5/24

(52) U.S. Cl. CPC G05F 3/16; H03B 5/24

(57) ABSTRACT

A current mirror with depletion mode MOS devices, and an embedded noise filter, operable with low supply voltage to provide a low-noise mirror current. The current mirror includes depletion-mode MOS transistors M1 and M2 configured as a current mirror, including a reference_current leg including M1 that receives an input reference current, and a mirror_current leg including M2, controlled by M1 to mirror the reference current as an output mirror current. An embedded noise filter (such as a low-pass RC filter) is coupled to M1 and M2, and configured to suppress noise in the input reference current from mirroring to the output mirror current. The embedded noise filter can be a low-pass RC coupled between the M1/M2 (low leakage) gates. Use of depletion-mode MOS devices with near-zero VT offers sufficient head-room for cascoding at low supply voltage to improve accuracy.

### CROSS-REFERENCE TO RELATED APPLICATIONS

Priority is claimed under 37 CFR 1.78 and 35 USC 119(e) to U.S. Provisional Application 62/037,428 (Docket TI-75281PS), filed 14 Aug. 2014, which is incorporated by reference.

### BACKGROUND

1. Technical Field

This Patent Disclosure relates generally to current mirror circuit designs.

2. Related Art

One application for current mirror circuits is to supply bias currents to VCOs (voltage controlled oscillators) used for clocking in optical networking devices.

Reducing power dissipation is often pursued by operating circuits at low supply voltage in deep-submicron CMOS processes. The combination of low supply voltages and deep-submicron CMOS devices leads to design challenges is generating VCO bias currents that are sufficiently low-noise to meet stringent clock jitter design constraints.

While this Background information references VCOs and optical networking, the Disclosure in this Patent Document is not limited to such applications, but is more generally directed to current mirror circuit design.

### BRIEF SUMMARY

This Brief Summary is provided as a general introduction to the Disclosure provided by the Detailed Description and Drawings, summarizing aspects and features of the Disclosure. It is not a complete overview of the Disclosure, and should not be interpreted as identifying key elements or features of, or otherwise characterizing or delimiting the scope of, the disclosed invention.

The Disclosure describes apparatus and methods for a current mirror with depletion mode MOS devices and embedded noise filter.

According to aspects of the Disclosure, the depletion-mode current mirror includes depletion-mode MOS transistors M1 and M2 configured as a current mirror. The current mirror includes a reference_current leg including M1 that receives an input reference current, and a mirror_current leg including M2, controlled by M1 to mirror the reference current as an output mirror current. The current mirror includes an embedded filter circuit coupled to M1 and M2, and configured to suppress noise in the input reference current from mirroring to the output mirror current. The embedded noise filter circuit, such as a low-pass RC filter, can be connected to the gates of M1 and M2. The depletion mode transistors (M1 and M2) can be either NMOS or PMOS transistors. Cascoding can be used to adjust the output mirror current (such as to improve accuracy), such as with cascode circuitry coupled to M2, and referenced to a voltage corresponding to the input reference current.

In an example application, the depletion-mode current mirror can be used to supply an output mirror current to a voltage controlled oscillator as an IVCO bias current.

Other aspects and features of the invention claimed in this Patent Document will be apparent to those skilled in the art from the following Disclosure.

### BRIEF DESCRIPTION OF THE DRAWINGS

FIG. 1 illustrates an example embodiment of a current mirror (10) based on depletion-mode MOS devices (MN1, MN2) with an embedded (RC) filter (15), in an example cascode (20) configuration.

### DETAILED DESCRIPTION

This Description and the Drawings constitute a Disclosure for a current mirror with depletion-mode MOS devices and an embedded noise filter, including illustrating various technical features and advantages.

This Disclosure references an example application for the depletion-mode current mirror in supplying a bias current IVCO for a voltage controlled oscillator. The Disclosed depletion-mode current mirror has general application in supplying an output mirror current (such as IVCO), mirrored from an input reference current (IREF) by a current mirror based on depletion-mode MOS and including embedded noise filtering.

In Brief overview, a current mirror with depletion mode MOS devices, and an embedded noise filter, operable with low supply voltage to provide a low-noise mirror current. The current mirror includes depletion-mode MOS transistors M1 and M2 configured as a current mirror, including a reference_current leg including M1 that receives an input reference current, and a mirror_current leg including M2, controlled by M1 to mirror the reference current as an output mirror current. An embedded noise filter is coupled to M1 and M2, and configured to suppress noise in the input reference current from mirroring to the output mirror current. The embedded noise filter can be a low-pass RC coupled between the M1/M2 (low leakage) gates. Use of depletion-mode MOS devices with near-zero VT offers sufficient head-room for cascoding at low supply voltage to improve accuracy.

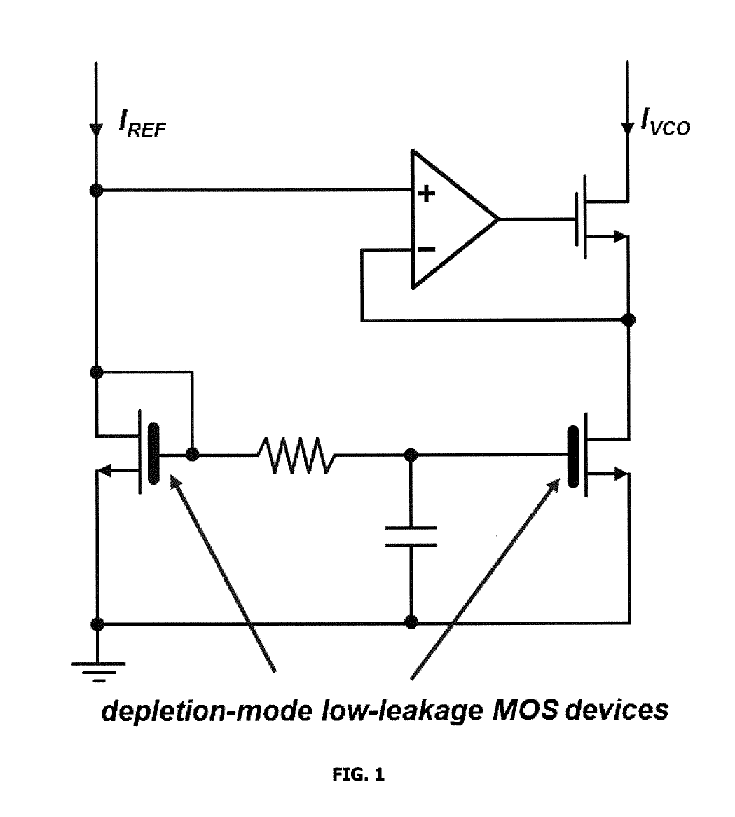

FIG. 1 illustrates an example functional embodiment of a current mirror based on depletion-mode MOS devices with embedded noise filtering. A current mirror 10 includes depletion-mode (near zero VT) NMOS transistors MN1 and MN2. Current mirror 10 includes an embedded noise filter that, for the example embodiment, is functionally represented by an RC filter 15 coupled to the MN1/MN2 gates.

Current mirror 10 receives an input reference_current IREF that is mirrored as an output mirror_current, designated in FIG. 1 as IVCO. IREF can be provided by a bandgap reference and a resistor (V to I).

In the example current mirror configuration, MN1 forms a reference_current-to-voltage leg (source-gate connected for negative feedback) that converts IREF to a control voltage for MN2. MN2 forms a voltage-to-mirror_current leg, mirroring IREF through MN2 as source-current IVCO.

Current mirror 10 includes an embedded noise filter. For the example functional embodiment, the embedded noise filter is represented by a low-pass RC filter 15, coupled between the MN1/MN2 gates. The embedded noise filter rejects (suppresses) high frequency noise from the IREF circuit (appearing in the control voltage generated by the reference_current-to-voltage let of current mirror 10), as well as noise generated within the current mirror, providing noise shaping for the output mirror current IVCO.

For the embedded noise filter, the example design configuration takes advantage of low gate leakage to allow use of a relatively small RC filter (i.e., with larger R and smaller C). Alternative filter configurations (including single capacitor) can be used, based on noise-shaping design requirements/trade-offs.

The depletion-mode MOS MN1/MN2, with near-zero threshold voltage, offers sufficient head-room for cascoding at low supply voltages. Including a cascode circuit in the output of current mirror 10 can be used to improve IVCO accuracy.

For the example embodiment, current mirror 10 is configured with a cascode circuit 20 in the current mirror output (IVCO). Cascode 20 is functionally represented by an NMOS transistor MN3 controlled by a buffer amplifier 21 referenced to the current mirror input (IREF). Alternative cascode configurations can be used, based on design requirements/trade-offs.

While the example embodiment of a current mirror based on depletion-mode MOS is described for an NMOS implementation, depletion-mode PMOS implementations can also be used, including with cascoding.

Process engineering can be used to enhance the MOS (NMOS or PMOS) devices for particular applications/optimizations. For example, output resistance can be increased, and parasitics can be reduced.

The Disclosed current mirror with depletion-mode MOS and embedded noise filtering provides a low-noise output mirror current, while operating at low supply voltages. The embedded noise filter rejects high-frequency noise from being mirrored to the output. Use of depletion-mode MOS devices with near-zero VT offers sufficient head-room for cascoding at low supply voltage to improve accuracy.

As an example application, the Disclosed current mirror design provides a precise current mirror a low supply voltage that can be used to provide a low-noise IVCO bias current suitable as reference to a low phase noise VCO.

The Disclosed current mirror with depletion-mode MOS devices and an embedded noise filter includes depletion-mode MOS transistors M1 and M2 configured as a current mirror (10). Current mirror (10) includes a reference_current leg including M1 that receives an input reference current, and a mirror_current leg including M2, controlled by M1 to mirror the reference current as an output mirror current. Current mirror (10) includes an embedded filter circuit coupled to M1 and M2, and configured to suppress noise in the input reference current from mirroring to the output mirror current. The embedded noise filter, such as a low-pass RC filter, can be connected to the (low-leakage) gates of M1 and M2. The depletion mode transistors (M1 and M2) can be either NMOS or PMOS transistors. Cascoding can be used to adjust the output mirror current (such as to improve accuracy), such as with cascode circuitry coupled to M2, and referenced to a voltage corresponding to the input reference current.

The Disclosure provided by this Description and the FIGURE sets forth example embodiments and applications illustrating aspects and features of the invention, and does not limit the scope of the invention, which is defined by the claims. Known circuits, functions and operations are not described in detail to avoid obscuring the principles and features of the invention. These example embodiments and applications can be used by ordinarily skilled artisans as a basis for modifications, substitutions and alternatives to construct other embodiments, including adaptations for other applications.

1. A current mirror circuit, comprising
depletion-mode MOS transistors M1 and M2 configured as a current mirror, including
a reference_current leg including M1 that receives an input reference current, and
a mirror_current leg including M2, controlled by M1 to mirror the reference current as an output mirror current; and
an embedded filter circuit coupled to M1 and M2, and configured to suppress noise in the input reference current from mirroring to the output mirror current.

2. The circuit of claim 1, wherein the embedded noise filter circuit is connected to the gates of M1 and M2.

3. The circuit of claim 2, wherein the embedded filter circuit comprises a low-pass RC filter circuit.

4. The circuit of claim 1, wherein M1 and M2 are either NMOS or PMOS transistors.

5. The circuit of claim 1, further comprising
cascode circuitry coupled to M2, and referenced to a voltage corresponding to the input reference current;
the cascode circuitry configured to adjust the output mirror current.

6. The circuit of claim 1, wherein the output mirror current is supplied to a voltage controlled oscillator as an IVCO bias current.

7. A circuit, comprising
a voltage controlled oscillator configured to generate a signal with a frequency controlled by a control voltage, and operable with a bias current IVCO;
a bias current generation circuit configured to provide IVCO, including current mirror circuitry;
the current mirror circuitry including
depletion-mode MOS transistors M1 and M2 configured as a current mirror, including
a reference_current leg including M1 that receives an input reference current, and
a mirror_current leg including M2, controlled by M1 to mirror the reference current as an output mirror current; and
an embedded filter circuit coupled to M1 and M2, and configured to suppress noise in the input reference current from mirroring to the output mirror current.

8. The circuit of claim 7, wherein the embedded noise filter circuit is connected to the gates of M1 and M2.

9. The circuit claim 8, wherein the embedded filter circuit comprises a low-pass RC filter circuit.

10. The circuit of claim 7, wherein M1 and M2 are either NMOS or PMOS transistors.

11. The circuit of claim 1, further comprising
cascode circuitry coupled to M2, and referenced to a voltage corresponding to the input reference current;
the cascode circuitry configured to adjust the output mirror current.

12. A method suitable for generating a controlled current, comprising generating a reference current;
converting the reference current to a control voltage, using a depletion-mode MOS transistor M1;
generating, in response to the control voltage, an output mirror current that mirrors the reference current, using a depletion-mode MOS transistor M2; and
filtering the control voltage to suppress noise in the input reference current from mirroring to the output mirror current.

13. The method of claim 12, wherein filtering is accomplished by an embedded noise filter connected to the gates of M1 and M2.

14. The method of claim 13, wherein the embedded noise filter comprises a low-pass RC filter.

15. The method of claim 12, wherein M1 and M2 are either NMOS or PMOS transistors.

16. The method of claim 12, further comprising
adjusting the output mirror current using cascoding based on a reference voltage corresponding to the input reference current.

17. The method of claim 12, wherein the output mirror current is supplied to a voltage controlled oscillator as an IVCO bias current.
